(19) United States
(12) Patent Application Publication
(10) Pub. No.: US 2008/0111224 A1
(43) Pub. Date: May 15, 2008

(54) Multi stack package and method of fabricating the same

(76) Inventors: Hak-kyoon Byun, Asan-si (KR); Tae-je Cho, Yongin-si (KR); Jong-bo Shim, Cheonan-si (KR); Sang-uk Han, Hwaseong-si (KR)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/790,962

(22) Filed: Apr. 30, 2007

(30) Foreign Application Priority Data
Nov. 9, 2006 (KR) 10-2006-0110538

(51) Int. Cl. H01L 23/02; H01L 21/00

(52) U.S. Cl. 257/686; 438/109; 257/E23.18; 257/E21.001

(57) ABSTRACT

Embodiments of the present invention provide a MSP having an upper and lower package, with a recess opening in the substrate of the upper package. The upper package may also include multiple stacked semiconductor chips. A lower package may include a substrate and at least one semiconductor chip. During assembly, portions of a lower package are placed into the recess opening in the substrate of the upper package. The beneficial result is a two-package MSP assembly with a reduced total height. In addition, the size and pitch of solder balls or other joints between the upper package substrate and the lower package substrate may also be reduced.

### CROSS-REFERENCE TO RELATED APPLICATION

This application claims the benefit of Korean Patent Application No. 10-2006-0110538, filed on Nov. 9, 2006, in the Korean Intellectual Property Office, the disclosure of which is incorporated herein in its entirety by reference.

### BACKGROUND OF THE INVENTION

1. Field of the Invention

The present invention relates to a semiconductor chip package and a method of fabricating the same, and more particularly, to a multi stack package (MSP) having a plurality of stacked semiconductor chips, and a method of fabricating the same.

2. Description of the Related Art

With the development of the semiconductor industry, electronic devices are becoming smaller, lighter and multifunctional. A multi stack package (MSP) has been developed to incorporate multiple semiconductor devices (or chips) into one unit package. As used herein, a MSP or package refers to an electronic assembly. The MSP has improved size, weight, and mounting area compared with individual semiconductor chip packages.

FIG. 1 is a cross-sectional view illustrating the structure of a conventional multi stack package (MSP).

Referring to FIG. 1, a conventional MSP 10 has a stack structure in which a lower package 12 includes a semiconductor chip 22 on a substrate 20 covered by an encapsulant 28, and an upper package 14 includes a stack module on a substrate 30 covered by an encapsulant 38 and having vertically stacked and aligned semiconductor chips 32 and 34. Lands 26 and 36 are formed respectively on the substrate 20 and the substrate 30 for electrically connecting the substrates to an external circuit. The lower package 12 is electrically connected to the upper package 14 by solder balls 40, which serve as joints between the lands 26 and the lands 36. As used herein, a joint is an electrically-conductive element that provides an electrical connection between two other elements of a MSP.

In the structure of the MSP 10 illustrated in FIG. 1, the total height h of the MSP 10 is determined, in part, by the height h₁ of the lower package 12 and the height h₂ of the upper package 14. In order to obtain a small total height h of the MSP 10, it is necessary to reduce the height h₁ of the lower package 12 and the height h₂ of the upper package 14. This can be done by reducing the height of the semiconductor chip 22 in the package 12 and the heights of the semiconductor chips 32 and 34 in the package 14, by reducing the height from the upper surface of the semiconductor chip 22 to the upper surface of the encapsulant 28 and the height from the upper surface of the semiconductor chip 34 to the upper surface of the encapsulant 38, or by reducing the thicknesses of the substrates 20 and 30. However, these methods are difficult to apply due to technical limitations in the packaging process.

Furthermore, since a gap must be provided between the lower package 12 and the upper package 14 due to the height h₃ of the semiconductor chip 22 and encapsulant 28, it is impossible to reduce the sizes of solder balls 40 between the lower package 12 and the upper package 14 to a desired size. Accordingly, there is a limit to the pitch of the solder balls and thus the density of input/output lines formed within the limited space of the substrate.

### SUMMARY OF THE INVENTION

Embodiments of the present invention provide a MSP having an upper and lower package, with a recess opening in the substrate of the upper package. The upper package may also include multiple stacked semiconductor chips. A lower package may include a substrate and at least one semiconductor chip. During assembly, portions of a lower package are placed into the recess opening in the substrate of the upper package. The beneficial result is a two-package MSP assembly with a reduced total height. In addition, the size and pitch of solder balls or other joints between the upper package substrate and the lower package substrate may also be reduced.

According to an aspect of the present invention, there is provided a multi stack package including a first package including a first substrate and a first semiconductor chip, the first semiconductor chip mounted to the first substrate with a first adhesive layer, the first substrate having a first opening, the first opening being substantially aligned in a vertical direction with respect to the first semiconductor chip; and a second package coupled to the first package, the second package including a second substrate and a second semiconductor chip, the second semiconductor chip mounted to the second substrate with a second adhesive layer, the second semiconductor chip being substantially aligned in the vertical direction with respect to the first opening, at least a portion of the second package extending into a space defined by the first opening such that the height of the multi stack package is less than a sum of heights associated with the first package and the second package.

According to another aspect of the present invention, there is provided a method of fabricating a multi stack package. The method includes: mounting a first semiconductor chip onto a first substrate, mounting the first semiconductor chip including applying a first adhesive layer to the first substrate; mounting a second semiconductor chip onto a second substrate; encapsulating the second semiconductor chip to form an encapsulated second semiconductor chip; removing a portion of the first substrate to create a first opening, the first opening being substantially aligned in a vertical direction with respect to the first semiconductor chip; and inserting at least a portion of the encapsulated second semiconductor chip into the first opening.

According to another aspect of the present invention, there is provided a method of fabricating a multi stack package. The method includes: removing a portion of a first substrate to create a first opening; mounting a first semiconductor chip onto the first substrate, the first semiconductor chip being substantially aligned in a vertical direction with respect to the first opening, mounting the first semiconductor chip including applying a first adhesive layer to the first substrate; mounting a second semiconductor chip onto a second substrate; encapsulating the second semiconductor chip to form an encapsulated second semiconductor chip; and inserting at least a portion of the encapsulated second semiconductor chip into the first opening.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view illustrating the structure of a conventional multi stack package (MSP);

FIG. 2 is a cross-sectional view of a multi stack package according to an embodiment of the present invention;

FIG. 3 is a cross-sectional view of a multi stack package according to another embodiment of the present invention;

FIG. 4 is a cross-sectional view of a multi stack package according to still another embodiment of the present invention;

FIG. 5 is a cross-sectional view of a multi stack package according to still another embodiment of the present invention;

FIG. 6 is a flowchart illustrating a method of fabricating a multi stack package, according to an embodiment of the invention;

FIG. 7 is a flowchart illustrating a method of fabricating a multi stack package, according to another embodiment of the invention; and

FIGS. 8 through 10 are cross-sectional views illustrating some sequential processes of the method of fabricating the multi stack package according to the embodiment of the present invention illustrated in FIG. 7.

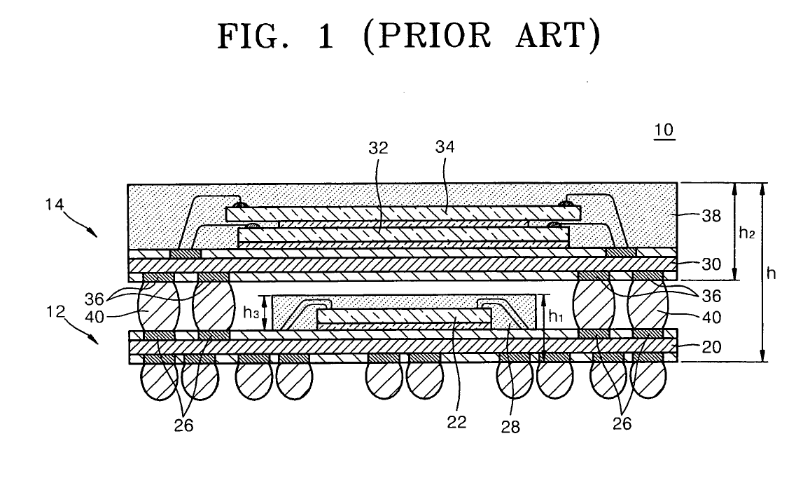

### DETAILED DESCRIPTION OF THE INVENTION

The present invention will now be described more fully with reference to the accompanying drawings, in which preferred embodiments of the invention are shown. This invention may, however, be embodied in many different forms, and should not be construed as being limited to the embodiments set forth herein. Rather, these embodiments are provided so that this disclosure will be thorough and complete, and will fully convey the scope of the invention to those skilled in the art. Like numbers refer to like elements throughout the specification.

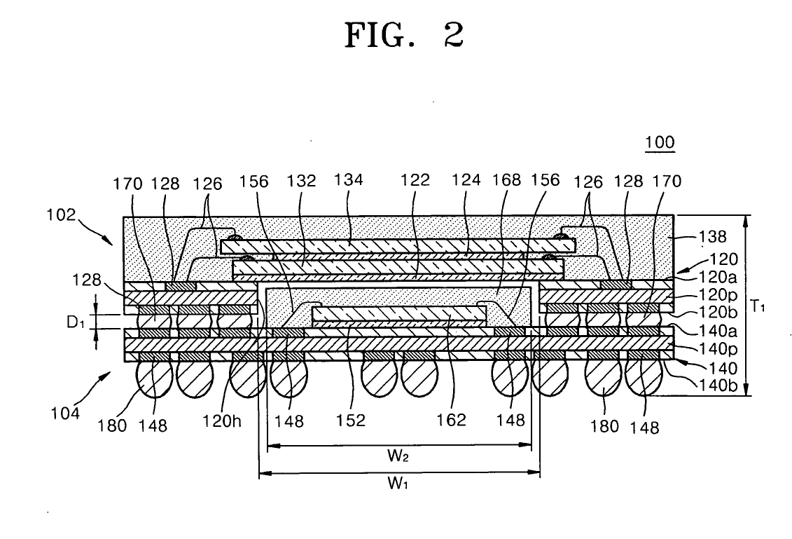

FIG. 2 is a cross-sectional view of a multi stack package 100 according to an embodiment of the present invention.

Referring to FIG. 2, the multi stack package 100 according to an embodiment of the present invention includes a package 102 and a package 104, which are stacked vertically.

The upper package 102 includes a substrate 120 having opposite surfaces 120a and 120b. Semiconductor chip 132 is mounted on surface 120a of the substrate 120, and semiconductor chip 134 is mounted on a surface of semiconductor chip 132. The substrate 120 may be a typical printed circuit board (PCB), a flexible PCB, a silicon substrate, a ceramic substrate, or other substrate technology.

The substrate 120 includes an opening 120h on an opposite side of the substrate with respect to the semiconductor chips 132 and 134. The opening 120h is smaller than the footprint of the semiconductor chip 132. The opening 120h is vertically aligned with the semiconductor chip 132. In the multi stack package 100 illustrated in FIG. 2, the opening 120h is in the form of a through hole passing through the substrate 120. However, the present invention is not limited thereto. For example, the opening 120h may have a depth less than the total thickness of the substrate 120, not passing through the substrate 120. In the package 102 of the multi stack package 100 illustrated in FIG. 2, an adhesive layer 122 is exposed through the opening 120h and faces the semiconductor chip 162 encapsulated by an encapsulant 168.

The substrate 120 further includes a conductive pattern region 120p around the opening 120h. The semiconductor chip 132 is fixed to the surface 120a of the substrate 120 by the adhesive layer 122, and the semiconductor chip 134 is fixed to the upper surface of the semiconductor chip 132 by an adhesive layer 124. The semiconductor chips 132 and 134 are coupled to exposed conductive lands 128 on surface 120a of the substrate 120 by bonding wires 126, and electrically connected to the substrate 120. The semiconductor chips 132 and 134 and the bonding wires 126 are encapsulated by an encapsulant 138 such as epoxy molding compound (EMC).

In the multi stack package 100 according to an embodiment of the present invention illustrated in FIG. 2, the package 102 is shown as including the semiconductor chip stack module having two sequentially stacked semiconductor chips 132 and 134. However, the present invention is not limited thereto, and the first package 102 may include a semiconductor chip stack module having three or more sequentially stacked semiconductor chips.

The lower package 104 includes a substrate 140 having opposite surfaces 140a and 140b, and a semiconductor chip 162 mounted on surface 140a of the substrate 140. The package 104 also includes encapsulant 168. The substrate 140 may be a typical PCB, a flexible PCB, a silicon substrate, a ceramic substrate, or other substrate technology, according to design choice.

The substrate 140 includes a conductive pattern region 140p under and around the semiconductor chip 162. The semiconductor chip 162 is attached to surface 140a of the substrate 140 by an adhesive layer 152. The semiconductor chip 162 is coupled to exposed conductive lands 148 on surface 140a of the substrate 140 by bonding wires 156, and electrically connected to the substrate 140. The semiconductor chip 162 and the bonding wires 156 are encapsulated by an encapsulant 168, such as EMC. The encapsulant 168 may be formed through a partial molding process, such as a top gate mold process, to encapsulate only the semiconductor chip 162 and the bonding wires 156 on the substrate 140. Accordingly, a portion of surface 140a around the semiconductor chip 162 and the bonding wire 156 is exposed instead of being covered by the encapsulant 168. Further, in the illustrated embodiment, a plurality of joints 180 for electrically connecting the second substrate 140 to an external circuit board are bonded to the exposed lands 148 on surface 140b of the second substrate 140.

At least a portion of the package 104 is inserted into the opening. 120h formed in the first substrate 120. The width W₂ of the encapsulant 168 encapsulating the semiconductor chip 162 on the substrate 140 may be equal to or less than the width W₁ of the opening 120h formed in the first substrate 120.

The upper package 102 and the lower package 104 are electrically connected to each other by joints 170, which are connected between the lands 128 on the surface 120b of substrate 120 and the lands 148 on surface 140a of substrate 140. In the multi stack package 100 illustrated in FIG. 2, the joints 170 are shown as being metal bumps such as solder balls.

In alternative embodiments, the joints 170 and/or the joints 180 could be elastomeric conductors, wire bonds, or another electrical conductor, according to design choice.

According to embodiments of the present invention, the total thickness T₁ of the multi stack package 100 can be reduced by the thickness of the portion of the second package 104 that is inserted into opening 120h, without having to reduce the thicknesses of the package 102 and/or the package 104. This eliminates the need for a separate carrier frame for supporting thinner substrates when fabricating the packages 102 and 104, thus reducing the fabrication cost. It also eliminates the need for a complicated process for handling the thinner substrates, thus simplifying the fabrication process. Furthermore, it is possible to reduce the possibility of warpage of the substrates and co-planarity inferiority when forming the package 102 and the package 104. In addition, the distance D₁ between the substrate 120 and the substrate 140 is small. This allows small joints 170 between the substrates 120 and 140, and thus reduces the pitch of the joints 170, such that the density of interconnection patterns formed within the limited area of the substrate increases. In addition the opening 120h formed in the package 102 serves as an engagement guide to prevent alignment errors when assembling the package 102 with the package 104.

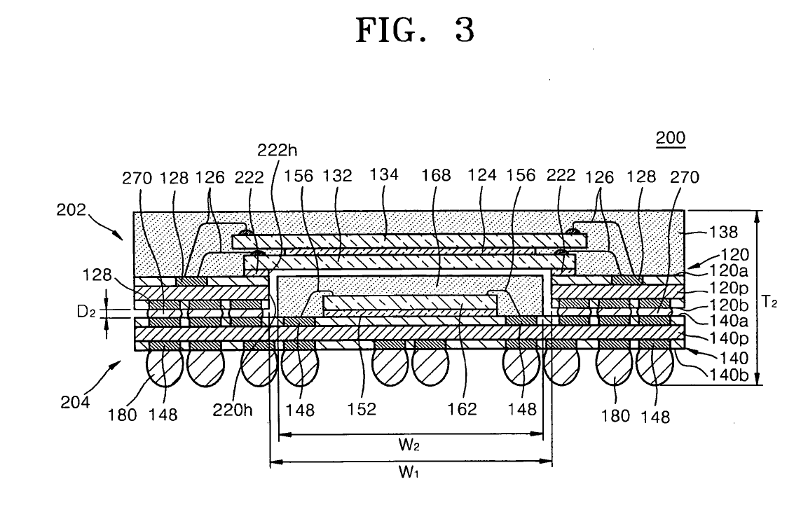

FIG. 3 is a cross-sectional view of a multi stack package 200 according to another embodiment of the present invention.

The multi stack package 200 illustrated in FIG. 3 is substantially similar to the multi stack package 100 according to the embodiment of the present invention illustrated in FIG. 2, except for the following. In FIG. 3, reference numbers common to FIG. 2 refer to equivalent elements, and thus the detailed description of those elements will not be repeated.

For the multi stack package 200 according to another embodiment of the present invention, in a package 202, a semiconductor chip 132 is fixed to a surface 120a of substrate 120 by an adhesive layer 222. The adhesive layer 222 includes an opening 222h that is substantially aligned with the opening 220h in the substrate 120. A portion of a surface of the semiconductor chip 132 is exposed through the opening 220h and the opening 222h to the encapsulant 168 of the semiconductor chip 162.

At least a portion of the package 204 is inserted into the opening 220h and/or the opening 222h. This results in a small distance D₂ between the substrate 120 and the substrate 140.

In the multi stack package 200 according to the embodiment of the present invention illustrated FIG. 3, the distance D₂ between the substrate 120 and the substrate 140 may be smaller than the distance D₁ illustrated in FIG. 2. As a result, the total thickness T₂ of the multi stack package 200 can be less than the total thickness T₁ of the multi stack package 100. Furthermore, the joints 270 between the substrate 120 and the substrate 140 can be smaller than the joints 170 of FIG. 2, and thus can be spaced at a reduced pitch, increasing the density of interconnection patterns formed within a limited area.

In alternative embodiments, the joints 270 could be solder bumps, elastomeric conductors, wire bonds, or another electrical conductor, according to design choice.

The packages 202 and 204 have the same structure as the packages 102 and 104 of FIG. 2, respectively, except for the features described above.

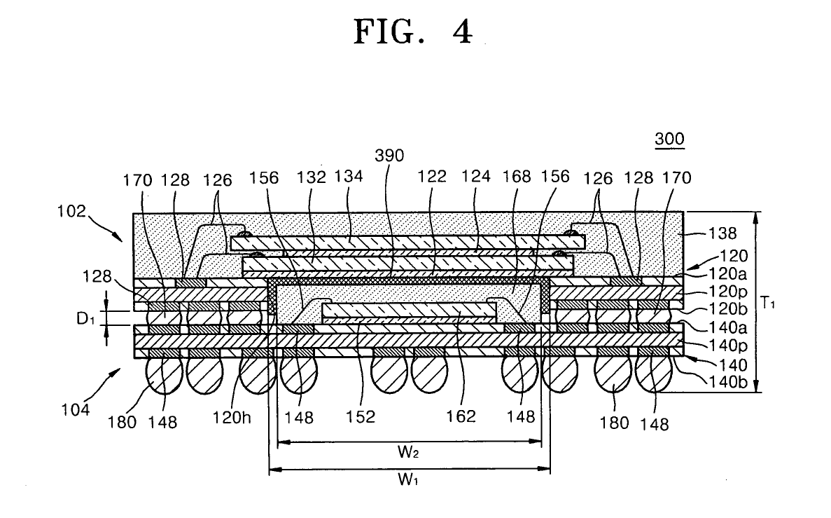

FIG. 4 is a cross-sectional view of a multi stack package 300 according to still another embodiment of the present invention.

The multi stack package 300 illustrated in FIG. 4 is substantially similar in structure to the multi stack package 100 according to the embodiment illustrated in FIG. 2, except for the following. In FIG. 4, reference numbers common to those in FIG. 2 refer to equivalent elements, and thus the detailed description of those elements will not be repeated.

According to this embodiment of the present invention, a multi stack package 300 includes an inter-package gap filler 390 formed in the opening 120h of the package 102 and interposed between the package 102 and the package 104.

The inter-package gap filler 390 extends along at least a portion of the sidewall of the opening 120h and the lower surface of the package 102. In the multi stack package 300 according to the embodiment of the present invention illustrated in FIG. 4, the inter-package gap filler 390 is bonded to the lower surface of the adhesive layer 122.

The inter-package gap filler 390 may be, for example, an epoxy resin paste or an adhesive material film. Alternatively, the inter-package gap filler 390 may be or include a non-adhesive material, such as a thermal compound. The thermal compound may include, for example, a semiconductor, metal, metal oxide, and/or an organic material. In particular, the thermal compound may include, for example, silicon (Si), gold (Au), silver (Ag), Copper (Cu), zinc oxide (ZnO₂), and/or silver oxide (AgO₂). Alternatively, the inter-package gap filler 390 may be or include, for example, an epoxy resin with an electrically-conductive filler, such as Ag, nickel (Ni), Au-coated Ni and lead (Pb). Alternatively, the inter-package gap filler 390 may be or include an electrically non-conductive material such as a filler that includes silicon dioxide (SiO₂), rubber-coated SiO₂, and/or rubber.

In the multi stack package 300 according to this embodiment of the present invention, the inter-package gap filler 390 can protect a part of the package 102 that is exposed through the opening 120h. Further, the inter-package gap filler 390 can reinforce the engagement between the packages 102 and 104, thus improving the reliability of the multi stack package 300. When the inter-package gap filler 390 is formed of a thermal compound, heat from the multi stack package 300 radiates through the inter-package gap filler 390 to the exterior, which improves the heat-radiating characteristics of the multi stack package 300, and in turn, the reliability of the multi stack package 300.

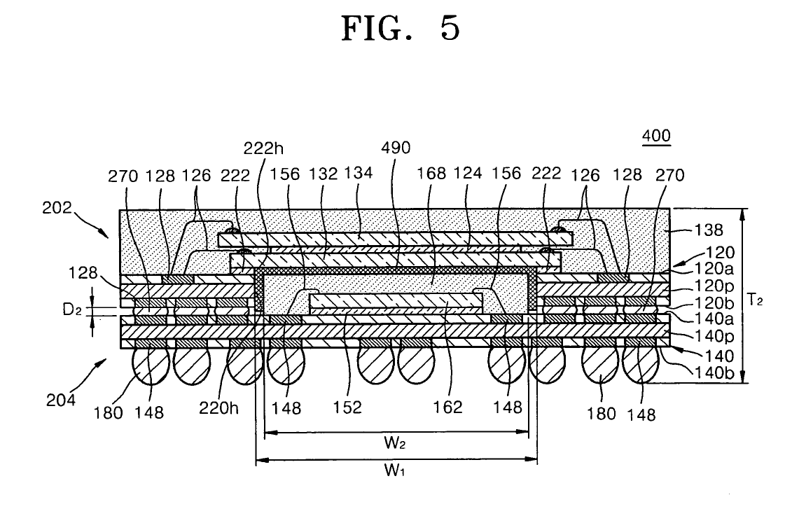

FIG. 5 is a cross-sectional view of a multi stack package 400 according to still another embodiment of the present invention.

The multi stack package 400 illustrated in FIG. 5 is substantially similar in structure to the multi stack package 200 according to the embodiment illustrated in FIG. 3, except for the following. In FIG. 5, reference numbers common to those in FIG. 3 refer to equivalent elements, and thus the detailed description of those elements will not be repeated.

According to this embodiment of the present invention, the multi stack package 400 includes an inter-package gap filler 490 formed in a opening 220h of a first package 202 and interposed between the packages 202 and 204. A detailed description of the inter-package gap filler 490 will be omitted since it is the same as the inter-package gap filler 390 of FIG. 4. However, in the multi stack package 300 according to the embodiment of the present invention illustrated in FIG. 5, the inter-package gap filler 490 extends along at least a portion of the sidewalls of openings 220h and 222h, and the lower surface of the first package 202 that is exposed through the openings 220h and 222h. In the multi stack package 300 according to the embodiment of the present invention illustrated in FIG. 5, the inter-package gap filler 490 contacts the lower surface of a semiconductor chip 132.

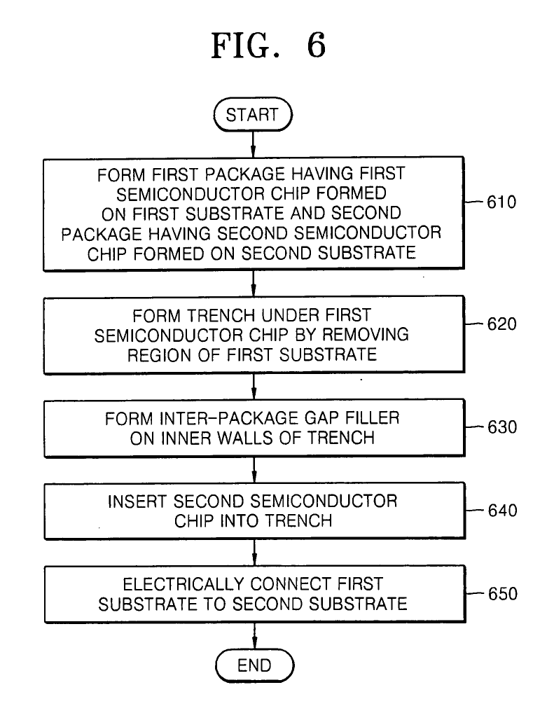

FIG. 6 is a flowchart illustrating a method of fabricating a multi stack package, according to an embodiment of the invention.

In process 610, a first semiconductor chip is assembled onto surface 120a of the first substrate 120 to form the first package 102 or 202. The first semiconductor chip may be a semiconductor chip stack module having two stacked semiconductor chips 132 and 134 as illustrated in FIGS. 2 through 5, or three or more sequentially stacked semiconductor chips. Process 610 also includes assembling a second semiconductor chip 162 onto surface 140a of a second substrate 140 to form a second package 104 or 204.

Process 610 may further include wire bonding and/or encapsulation steps. For example, forming the first package 102 or 202 may include adding bond wires 126 and encapsulant 138 to the first package 102 or 202. Likewise, forming the second package 104 or 204 may include adding bond wires 156 and encapsulant 168.

In process 620, a region of the first substrate 120 of the first package 102 or 202 is removed from the second surface 120b to form a trench under the first semiconductor chip. The trench may be the first opening 120h in the examples of FIGS. 2 and 4. In this case, only a region of the first substrate 120 may be removed to form the first opening 120h as a trench passing through the first substrate 120.

Alternatively, a portion of the first substrate 120 may be removed and then a portion of the first adhesive layer 222 that is exposed through the first opening 120h may also be removed in process 620. In this instance, the trench formed in process 620 is a combination of the first opening 220h and the second opening 222h in the example of FIGS. 3 and 5.

In yet another embodiment of process 620, a lower surface of the semiconductor chip 132 that is exposed through the first opening 220h and the second opening 222h may also be removed. For example, in order to remove a predetermined thickness from the lower surface of the semiconductor chip 132, a portion of bulk silicon substrate on a back side of the semiconductor chip 132 can be removed.

In process 630, the inter-package gap filler 390 or 490 is formed in the trench. An adhesive material film may be adhered to the inner walls of the trench in order to form the inter-package gap filler 390 or 490. Alternatively, a non-adhesive material can be dry-coated on the inner walls of the trench in process 630.

In process 640, at least a portion of the second package 104 or 204 (e.g., at least a portion of the encapsulant 168) is inserted into the trench. In performing process 640, at least portions of the encapsulant 168 may contact the inter-package gap filler 390 or 490.

In process 650, the first substrate 120 is electrically connected to the second substrate 140. Specifically, the joints 170 or 270 such as metal bumps connected to the lands 128 on the second surface 120b of the first substrate 120 may be bonded to the lands 148 on the third surface 140a of the second substrate 140. The joints 170 or 270 may be, for example, solder balls that include lead (Pb). The process of bonding the joints 170 or 270 of the first package 102 or 202 to the lands of the second package 104 or 204 may be performed at a temperature of about 240° C., in a furnace.

Variations to the method illustrated in FIG. 6 are possible. For example, in one alternative embodiment, process 630 may be omitted altogether to form the MSP 100 or 200 of FIG. 2 or 3, respectively. Moreover, in yet another alternative embodiment, process 630 can be performed subsequent to process 640; in this instance, the inter-gap filler 390 or 490 is injected into the trench and around at least a portion of the encapsulant 168.

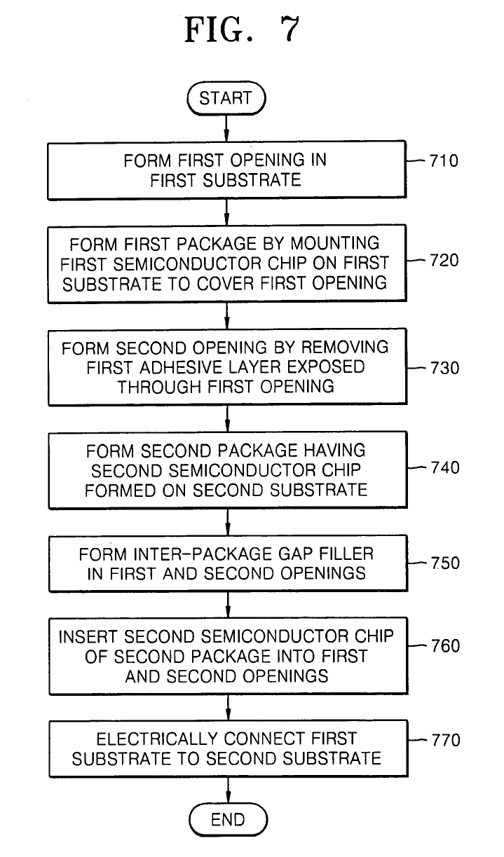

FIG. 7 is a flowchart illustrating a method of fabricating the multi stack package according to another embodiment of the invention.

In process 710, the first opening 120h or 220h is formed in a region of the first substrate 120.

In process 720, the first semiconductor chip is mounted on the first surface 120a of the first substrate 120. In this case, the first semiconductor chip is positioned to cover at least a portion of the first opening 120h or 220h. A detailed description of the first semiconductor chip will be omitted, since it is the same as that in connection with process 610 of FIG. 6. The first adhesive layer 122 and the second adhesive layer 124 may be used to attach the first semiconductor chip to the first substrate 120. Process 720 may further include adding the wire bonds 126 and the encapsulant 138.

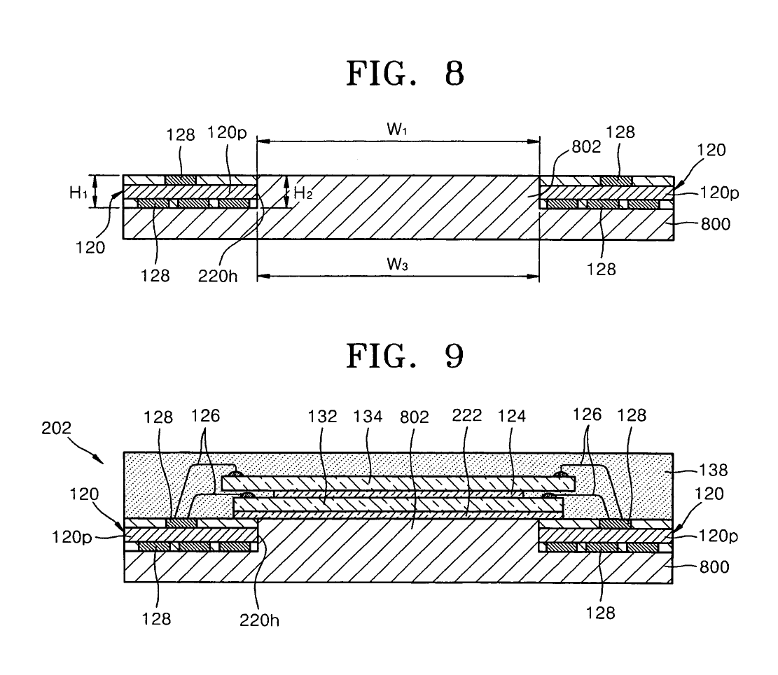

An embodiment of process 720 that utilizes a mounting table is described with reference to FIGS. 8 and 9.

FIG. 8 is a cross-sectional view of the first substrate 120 having the first opening 220h located on the mounting table 800 in order to mount the first semiconductor chip on the first substrate 120. In the illustrated embodiment, the mounting table 800 has a protrusion 802 on its upper surface. The protrusion 802 may have a width W₃ that is equal to or less than the width W₁ of the first opening 220h formed in the first substrate 120. The protrusion 802 may have a height H₂ that is equal to or less than the height H₁ of the first substrate 120. As shown in FIG. 8, the first semiconductor chip may be mounted on the first substrate 120 in a state where the protrusion 802 of the mounting table 800 is inserted into the first opening 220h.

FIG. 9 is a cross-sectional view of the semiconductor chips 132 and 134 mounted on the first substrate 120 using the first adhesive layer 222 and the second adhesive layer 124 in order to form the first package 202 in a state where the protrusion 802 of the mounting table 800 is inserted into the first opening 220h.

As illustrated in FIGS. 8 and 9, the semiconductor chips 132 and 134 are mounted on the first substrate 120 in a state where the first substrate 120 having the first opening 220h is mounted on the mounting table 800 having the protrusion 802, thus preventing warpage of the first substrate 120 when fabricating the first package 202, and facilitating handling of the substrate 120. Furthermore, a thinner substrate may be employed as the first substrate 120 in order to form the first package 202.

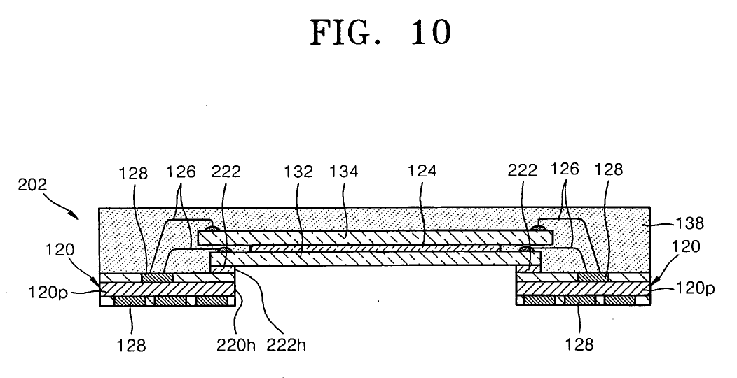

Referring back to FIG. 7, in process 730, the portion of the first adhesive layer 222 that is exposed through the first opening 220h of the first substrate 120 is removed to form the second opening 222h passing through the first adhesive layer 222. Accordingly, the lower surface of the semiconductor chip 132 is exposed through the first opening 220h and the second opening 222h, as illustrated in FIG. 10. Process 730 optionally includes removing a predetermined thickness from the exposed lower surface of the semiconductor chip 132.

Process 730 may further include adding joints 270 to the lands 128 of the first substrate 120. For example, the joints 270 may be coupled to the lands 128 in the second surface 120b of the first substrate 120 subsequent to forming the second opening 222h. Alternatively, the joints 270 may be coupled to the lands 128 in the second surface 120b of the first substrate 120 prior to forming the second opening 222h.

In process 740, the second semiconductor chip is mounted on the third surface 140a of the second substrate 140 to form the second package 104 or 204. The second semiconductor chip may be the semiconductor chip 162 illustrated in FIGS. 2 through 5. Process 740 may further include adding wire bonds 156 and encapsulant 168.

In process 750, the inter-package gap filler 390 or 490 is formed in the first opening 220h and the second opening 222h of the first package 202. A description of the process of forming the inter-package gap filler 390 or 490 will be omitted since it is the same as process 630 of FIG. 6. Process 750 may be omitted, according to design choice.

In process 760, at least a portion of the second package 104 or 204 (e.g., at least a portion of the encapsulant 168 encapsulating the semiconductor chip 162) is inserted into the first opening 220h and the second opening 222h. At least portions of the encapsulant 168 may contact the inter-package gap filler 390 or 490.

In process 770, the first substrate 120 is electrically connected to the second substrate 140, as in process 650 of FIG. 6.

Variations to the method illustrated in FIG. 7 are possible. For example, in one alternative embodiment, step 750 is performed after step 760; in this instance, step 750 includes injecting the cap filler 390 or 490 in the trench and around at least a portion of the encapsulant 168.

In another alternative embodiment to what is illustrated in FIG. 7, step 720 includes selective application of the first adhesive layer 222 so that no adhesive is exposed by the first opening 220h. In this case, step 730 is not required, since the second opening 222h is formed by the selective application of the first adhesive layer 222.

In the multi stack package according to the present invention, a portion of the second lower package is inserted into the trench or opening formed under the first upper package. The total thickness of the multi stack package according to the present invention can be reduced without having to reduce the thicknesses of the first package and the second package, that are engaged with each other. This eliminates the need for a separate carrier frame for supporting thinner substrates when fabricating the first and second packages, thus reducing the fabrication cost and simplifying the fabrication process. In addition, when the first package is aligned and engaged with the second package, the trench or opening formed in the first package serves as an engagement guide to prevent alignment errors between the packages. As the distance between the first substrate and the second substrate gets smaller, the sizes of the joints required for electrically connecting the substrates can be reduced, allowing a finer joint pitch and increasing the density of interconnection patterns formed within the limited area of the substrate. Thus, the present invention can be used for highly integrated high-performance integrated circuits.

While the present invention has been particularly shown and described with reference to exemplary embodiments thereof, it will be understood by those of ordinary skill in the art that various changes in form and detail may be made therein without departing from the spirit and scope of the present invention as defined by the following claims. For instance, where individual features are described in the alternative, the invention should be understood to include combinations of features that are claimed but not expressly illustrated or described in such combination.

What is claimed is:

1. A multi stack package comprising:
a first package including a first substrate and a first semiconductor chip, the first semiconductor chip mounted to the first substrate with a first adhesive layer, the first substrate having a first opening, the first opening being substantially aligned in a vertical direction with respect to the first semiconductor chip; and
a second package coupled to the first package, the second package including a second substrate and a second semiconductor chip, the second semiconductor chip mounted to the second substrate with a second adhesive layer, the second semiconductor chip being substantially aligned in the vertical direction with respect to the first opening, at least a portion of the second package extending into a space defined by the first opening such that the height of the multi stack package is less than a sum of heights associated with the first package and the second package.

2. The multi stack package of claim 1, wherein the second semiconductor chip is encapsulated by an encapsulant, and wherein at least a portion of the encapsulant extends into the space defined by the first opening.

3. The multi stack package of claim 1, wherein an inter-package gap filler exists in at least a portion of the space defined by the first opening.

4. The multi stack package of claim 3, wherein the inter-package gap filler is an adhesive material.

5. The multi stack package of claim 3, wherein the inter-package gap filler is a non-adhesive material.

6. The multi stack package of claim 3, wherein the inter-package gap filler is a thermal compound.

7. The multi stack package of claim 3, wherein the inter-package gap filler is an electrically-conductive material.

8. The multi stack package of claim 1, wherein the first adhesive layer includes a second opening, the second opening being substantially aligned in the vertical direction with respect to the first opening.

9. The multi stack package of claim 8, wherein an inter-package gap filler exists in at least a portion of the space defined by the first opening, and wherein the inter-package gap filler also exists in at least a portion of a space defined by the second opening.

10. The multi stack package of claim 1, wherein the first package includes a third semiconductor chip, the third semiconductor-chip being substantially aligned in the vertical direction with respect to the first semiconductor chip, the third semiconductor chip being mounted to the first semiconductor chip by a third adhesive layer.

11. A method of fabricating a multi stack package, the method comprising:
mounting a first semiconductor chip onto a first substrate, mounting the first semiconductor chip including applying a first adhesive layer to the first substrate;
mounting a second semiconductor chip onto a second substrate;
encapsulating the second semiconductor chip to form an encapsulated second semiconductor chip;
removing a portion of the first substrate to create a first opening, the first opening being substantially aligned in a vertical direction with respect to the first semiconductor chip; and
inserting at least a portion of the encapsulated second semiconductor chip into the first opening.

12. The method of claim 11, further comprising mounting a third semiconductor chip onto the first semiconductor chip, the third semiconductor chip being substantially aligned in the vertical direction with respect to the first semiconductor chip.

13. The method of claim 11, further comprising applying an inter-package gap filler into at least a portion of the first opening after removing the portion of the first substrate and before inserting at least the portion of the encapsulated second semiconductor chip.

14. The method of claim 11, further comprising removing a portion of the first adhesive layer exposed by the first opening after removing the portion of the first substrate and before inserting at least the portion of the encapsulated second semiconductor chip.

15. The method of claim 11, further comprising injecting an inter-package gap filler into at least a portion of the first opening after inserting at least the portion of the encapsulated second semiconductor chip.

16. A method of fabricating a multi stack package, the method comprising:
removing a portion of a first substrate to create a first opening;
mounting a first semiconductor chip onto the first substrate, the first semiconductor chip being substantially aligned in a vertical direction with respect to the first opening, mounting the first semiconductor chip including applying a first adhesive layer to the first substrate;
mounting a second semiconductor chip onto a second substrate;
encapsulating the second semiconductor chip to form an encapsulated second semiconductor chip; and
inserting at least a portion of the encapsulated second semiconductor chip into the first opening.

17. The method of claim 16, further comprising mounting a third semiconductor chip onto the first semiconductor chip, the third semiconductor chip being substantially aligned in the vertical direction with respect to the first semiconductor chip.

18. The method of claim 16, further comprising applying an inter-package gap filler into at least a portion of the first opening before inserting at least the portion of the encapsulated second semiconductor chip.

19. The method of claim 16, further comprising applying an inter-package gap filler into at least a portion of the first opening after inserting at least the portion of the encapsulated second semiconductor chip.

20. The method of claim 16, wherein applying a first adhesive layer is done selectively such that the first adhesive layer does not extend into the first opening.
